(19) United States
(12) Patent Application Publication
(10) Pub. No.: US 2020/0144307 A1
(43) Pub. Date: May 7, 2020

(54) ARRAY SUBSTRATE, MANUFACTURING METHOD OF THE ARRAY SUBSTRATE, AND DISPLAY DEVICE

(71) Applicant: HKC Corporation Limited, Shenzhen (CN)

(72) Inventor: Chuan Wu, Shenzhen (CN)

(21) Appl. No.: 16/278,103

(22) Filed: Feb. 17, 2019

Related U.S. Application Data
(63) Continuation of application No. PCT/CN2018/121841, filed on Dec. 18, 2018.

(30) Foreign Application Priority Data
Nov. 6, 2018 (CN) 201811317749.3

(51) Int. Cl. H01L 27/12; G02F 1/1362; G02F 1/1368

(52) U.S. Cl. CPC H01L 27/1244; H01L 27/1262; G02F 2202/22; G02F 1/136204; G02F 1/1368; G02F 1/136286

(57) ABSTRACT

Disclosed are an array substrate, a manufacturing method of the array substrate, and a display device. The array substrate includes a substrate which includes a display region and an edge region; a data line which includes a first end and a second end; a discharge line which is electrically connected to the second end of the data line; and an electrostatic discharge structure which is electrically connected with the discharge line. The manufacturing method of the array substrate includes: electrically connecting discharge line and one end of the data line away from the driving chip; electrically connecting the discharge line with the electrostatic discharge structure; disconnecting the discharge line and the data line, after the preparation of the array substrate is completed.

### CROSS REFERENCE TO RELATED APPLICATIONS

The present application is a Continuation Application of PCT Application No. PCT/CN2018/121841 filed on Dec. 18, 2018, which claims the benefit of Chinese Patent Application No. 201811317749.3, filed with the Chinese Patent Office on Nov. 6, 2018 and entitled “Array substrate, manufacturing method of the array substrate, and display device”, which is incorporated herein by reference in its entirety.

### TECHNICAL FIELD

The present application relates to the technical field of liquid crystal display, in particular, to an array substrate, a manufacturing method of the array substrate, and a display device.

### BACKGROUND

The statements herein merely provide background information related to the present application and do not necessarily constitute prior art.

During the manufacturing of the array substrate of Thin Film Liquid Crystal Display (TFT-LCD), electrostatic accumulation often occurs. Due to the demand of display, the array substrate is commonly made of insulated glass substrate, which leads to the problem of electrostatic discharge (ESD) in the process of manufacturing and transportation, resulting in the performance degradation and even destruction of the array substrate, thus reducing the yield of products.

### SUMMARY

The main purpose of the present application is to provide an array substrate, aiming at solving the problem of difficult releasing of static electricity on the array substrate during the manufacturing process of the array substrate.

In order to achieve the aforementioned objective, the present application provides an array substrate including:

a substrate, including a display region and an edge region located at a periphery of the display region;

a data line, including a first end and a second end, the first end connecting with a driving chip, and the second end extends to the edge region along a direction away from a side of the driving chip;

a discharge line, defined in the edge region and electrically connected with the second end of the data line; and,

an electrostatic discharge structure, electrically connected with the discharge line.

Optionally, an extension direction of the discharge line is perpendicular to an extension direction of the data line.

Optionally, the discharge line is integrally formed with the data line.

Optionally, two sides of the extension direction of the discharge line are electrically connected with the electrostatic discharge structure.

Optionally, the electrostatic discharge structure is an electrostatic ring or a tip discharge device.

Optionally, the discharge line is electrically connected with a plurality of electrostatic discharge structures. Optionally, there are a plurality of data lines, and each of the data lines is electrically connected with one discharge line.

Optionally, a plurality of discharge lines are defined, and the plurality of discharge lines are connected to each other.

Optionally, the discharge line is made of copper.

Optionally, the electrostatic discharge structure is an electrostatic ring or a tip discharge device.

Optionally, the tip discharge device is defined on a data line layer or a gate line layer on the substrate, when the electrostatic discharge structure is the tip discharge device.

The present application also provides a manufacturing method of the array substrate, which includes the following steps:

electrically connecting a discharge line and one end of a data line away from the driving chip;

electrically connecting the discharge line with an electrostatic discharge structure;

disconnecting the discharge line and the data line, after a preparation of the array substrate is completed.

Optionally, electrically connecting a discharge line and one end of a data line away from the driving chip includes the following steps:

forming the data line on the substrate and extending one end of the data line away from the driving chip to an edge region of the substrate opposite to the driving chip;

forming the discharge line on the edge region of the substrate opposite to the driving chip.

Optionally, the discharge line is formed integrally with the data line, when forming the discharge line on the edge region of the substrate opposite to the driving chip.

Optionally, all the data lines are electrically connected to one discharge line, when electrically connecting the discharge line and the one end of a data line away from the driving chip.

Optionally, two ends of the discharge line in an extending direction are respectively electrically connected to one electrostatic discharge structure, when electrically connecting the discharge line with an electrostatic discharge structure.

Optionally, the electrostatic discharge structure is a tip discharge device.

Optionally, the electrostatic discharge structure is an electrostatic ring. Optionally, the step of disconnecting the discharge line and the data line comprises disconnecting disconnecting the discharge line and the data line by laser cutting.

The present application also provides a display device, which includes an array substrate, and the manufacturing method of the array substrate includes the following steps:

electrically connecting a discharge line and one end of a data line away from the driving chip;

electrically connecting the discharge line with an electrostatic discharge structure;

disconnecting the discharge line and the data line, after a preparation of the array substrate is completed.

In the technical solution of the present application, by means of electrically connecting one end of the data line away from the driving chip with the discharge line and electrically connecting the discharge line with the electrostatic discharge structure, static electricity accumulated on the substrate can be released by transmitting the static electricity from the discharge line to the electrostatic discharge structure in the process of preparing the array substrate. After the array substrate is completed, the data line and the discharge line are disconnected, so as to facilitate following use of the array substrate. Compared with the exemplary technology, the technical solution of the present application can release the static electricity accumulated on the array substrate, effectively improve the yield of products. The connection between the data line and the discharge line is cut off after the array substrate is prepared, which does not adversely affect the structure and performance of the array substrate itself, and is convenient for mass production of the array substrate.

### BRIEF DESCRIPTION OF THE ACCOMPANYING DRAWINGS

In order to explain the embodiments of the present application or the technical solutions in the prior art more clearly, the drawings used in the embodiments or the description of the prior art will be briefly introduced below. Obviously, the drawings in the following description are only some embodiments of the present application. For those skilled in the art, some other drawings can be obtained according to the structures shown in these drawings without paying creative effort.

FIG. 1 is a schematic structural diagram of an array substrate in some embodiments of the present application;

FIG. 2 is a schematic structural diagram of a discharge line and a tip discharge device in the embodiments shown in FIG. 1;

FIG. 3 is a schematic structural diagram of a discharge line and a tip discharge device in some other embodiments of the array substrate of the present application;

FIG. 4 is a process flow diagram of the manufacturing method of the array substrate of the present application;

FIG. 5 is a schematic structural diagram after the data line and the discharge line are disconnected in the manufacturing method of the array substrate of the present application.

The implementation, functional features and advantages of the purpose of the present application will be further described with reference to the accompanying drawings in conjunction with the embodiments.

### DETAILED DESCRIPTION OF ILLUSTRATIVE EMBODIMENTS

The technical solution in the embodiment of the present application will be described clearly and completely in the following with reference to the drawings in the embodiment of the present application. Obviously, the described embodiment is only a part of the embodiment of the present application, but not all of the embodiments. Based on the embodiments in the present application, all other embodiments obtained by a person of ordinary skill in the art without creative effort are within the protection scope of the present application.

It should be noted that if directional indications (such as up, down, left, right, front, back, etc.) are involved in the embodiments of the present application, the directional indications are only used to explain the relative positional relationship and movement between the components in a certain posture (as shown in the drawings), and if the specific posture changes, the directional indications will change accordingly.

In addition, if there are descriptions of “first” and “second” in the embodiments of the present application, the descriptions of “first” and “second” are for descriptive purposes only and cannot be understood as indicating or implying their relative importance or implicitly indicating the number of indicated technical features. Thus, features defining “first” and “second” may explicitly or implicitly include at least one such feature. In addition, the meaning of “and/or” appearing in the full text is to include three parallel schemes, taking “a and/or b” as some embodiments, including solution of a or b, or solution that both a and b satisfy at the same time. In addition, the technical solutions between the various embodiments may be combined with each other, but must be based on what one of ordinary skill in the art can achieve. When the combination of technical solutions is contradictory or impossible to achieve, it should be considered that the combination of such technical solutions does not exist and is not within the protection scope required by the present application.

The present application provides an array substrate.

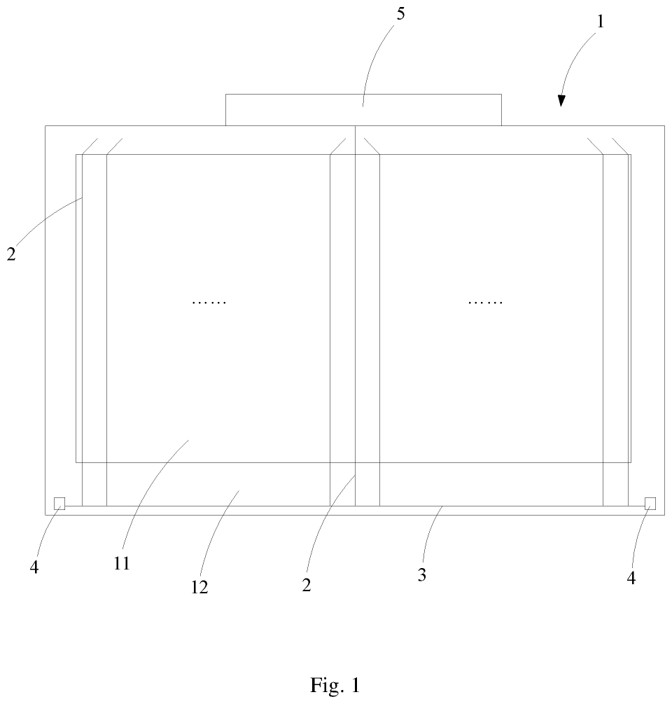

In some embodiments of the present application, as shown in FIG. 1, the array substrate includes a substrate 1, which may be an unprocessed array substrate used to prepare a fully functional array substrate or an array substrate already covered with a multilayer film layer. Specifically, the substrate 1 includes a display region 11 and an edge region 12, wherein the edge region 12 surrounds the periphery of the display region 11, that is, the edge region 12 is a non-display region 11 of the array substrate. In general, the edge region 12 is formed on the peripheral side of the display region 11, but in actual production, edge region 12 may be provided only on one side, two sides or three sides of the display region 11.

Optionally, the substrate 1 is covered with a plurality of data lines 2 and gate lines, in which the data lines 2 are formed on the data line layer 13 on the substrate 1 and the gate lines are formed on the gate line layer 14 on the substrate 1. Specifically, the two ends of the data line 2 in its signal transmission direction are respectively a first end and a second end, in which the first end is connected to the drive chip 5, i.e. the first end is the signal input end of the data line 2 for receiving and transmitting voltage signals to the substrate 1. The data line 2, from the drive chip 5, is laid in the display region 11 of the substrate 1 along its signal transmission direction and extends to the edge region 12 on the side of the substrate 1 away from the drive chip 5, and the second end of the data line 2 is located in the edge region 12.

Optionally, the array substrate further includes a discharge line 3 which is defined in the edge region 12 of the array substrate and electrically connected to the second end of the data line 2. It should be noted that in the technical solution provided by the present application, it is not limited that the discharge line 3 must be defined in the edge region 12 on one side of the display region 11. Regarding the discharge line 3, it may also be defined in the edge region 12 on two or three sides of the display region 11. In some embodiments, the discharge line 3 is only defined in the edge region 12 of the substrate 1 opposite to the driving chip 5, that is, the edge region 12 where the second end of the data line 2 is located. The discharge line 3 is defined in the edge region 12 of the substrate 1 opposite to the driving chip 5, which not only facilitates the electrical connection between the discharge line 3 and the data line 2, but also has little influence on other signal lines and electrodes on the substrate 1, and has negligible influence on the processing technology of the array substrate. Furthermore, the discharge lines 3 are only arranged in the edge region 12 at one side of the substrate 1, and the length of the discharge lines 3 can also be set relatively short, which can effectively reduce the cost when preparing the array substrate in batches.

Optionally, the array substrate further includes an electrostatic discharge structure 4 which is electrically connected to the discharge line 3.

During the preparation of the array substrate, the substrate 1 will collect static electricity in moving in different operation chambers and coating processes. Since the substrate 1 is of insulating property and the data line 2 is conductive, the data line 2 becomes the main carrier of static electricity on the substrate 1. During the preparation of the conventional array substrate, since the end of the data line 2 along a direction away from the driving chip 5 is a free end and is not connected to any equipment or structure, static electricity accumulated on the data line 2 cannot be released. When static electricity accumulates to a certain extent, electrostatic discharge will occur and break through the pixel electrode film layer on the substrate 1, resulting in breaking of the array substrate. According to the technical solution of the present application, the data line 2 is electrically connected with the electrostatic discharge structure 4 through the discharge line 3, in order to release the static electricity accumulated on the data line 2, thereby preventing the damage induced by the static electricity accumulated on the data line 2 to the film layer on the substrate 1.

Optionally, in some embodiments, all data lines 2 are electrically connected to one discharge line 3. It can be understood that by connecting one discharge line 3 to all data lines 2, the accumulated static electricity on all data lines 2 can be released at the same time, so that the static electricity on the substrate 1 can be more fully released, reducing the phenomenon in which the static electricity on some data lines 2 has already been released and some other static electricity remains on some other data lines 2. The accumulated static electricity on the substrate 1 is fully released. Moreover, since all data lines 2 are electrically connected to one discharge line 3, which is equivalent to each data line 2 being electrically connected to each other, charges can move between different data lines 2, so that charges on each data line 2 can be averaged. So excessive static electricity accumulated on one or more data lines 2 can be reduced and local electrostatic discharge can occur, and the protection of the array substrate can be enhanced. Additionally, since one discharge line 3 is provided, the space occupied by the discharge line 3 in the edge region 12 of the substrate 1 will be correspondingly reduced, and its influence on other structures and wiring on the substrate 1 will be small. This can avoid increasing the process difficulty due to the limitation of other wiring and structures around the discharge line 3 due to the excessive space occupied by the discharge line 3 and is beneficial to the preparation of the array substrate. Furthermore, considering the manufacturing cost of the array substrate, one discharge line 3 can naturally reduce the material cost of the discharge line 3 to improve the profit margin of the array substrate.

It should be noted that in other embodiments, a plurality of discharge lines 3 may be provided. A plurality of data lines 2 may be connected to one discharge line 3, or one data line 2 connected to one discharge line 3, and two or more discharge lines 3 may also be connected to each other. The specific arrangement needs to be adjusted according to factors such as the region of the array substrate, the difficulty of the processing process, and the manufacturing cost in actual production.

Optionally, in some embodiments, the extension direction of the discharge line 3 is perpendicular to the extension direction of the data line 2. It can be understood that since the data lines 2 are arranged in parallel on the substrate 1, if the extension direction of the discharge lines 3 is perpendicular to the data lines 2, the length of the discharge lines 3 can be shortened as much as possible while the discharge lines 3 and the data lines 2 are connected, so as to save the materials required for arranging the discharge lines 3 and further reduce the manufacturing cost of the array substrate. Additionally, compared with the discharge lines 3 of other design forms, the length of the discharge lines 3 arranged perpendicular to the data lines 2 is the shortest, the space occupied on the substrate 1 is made small, and accordingly, the interference to other elements on the substrate 1 is also small. Secondly, the processing technology of the discharge line 3 arranged in a straight line form is relatively simple and easy for production personnel to operate.

It should be noted that in other embodiments, the discharge line 3 can also be defined in other forms, such as curves, poly-lines, wavy lines, etc. In practical production applications, how to set the discharge line 3 still needs to be determined after comprehensive consideration according to process requirements and processing costs, etc.

Optionally, two sides of the extension direction of the discharge line are electrically connected with the electrostatic discharge structure. It can be understood that the advantage of electrically connecting the electrostatic discharge structure 4 on both sides of the discharge line 3 is that the static electricity accumulated on the data line 2 can be released more fully and more quickly, and the discharge capacity of the array substrate is improved to enhance the protection on the array substrate. When the electrostatic discharge structure 4 on one side of the discharge line 3 fails to work, the static electricity on the data line 2 can still be released through the electrostatic discharge structure 4 provided on the other side of the discharge line 3 without causing damage to the array substrate. Obviously, by providing the electrostatic discharge structure 4 on both sides of the discharge line 3, the fault tolerance rate of the electrostatic discharge device can be effectively improved to enhance the protection of the substrate 1 and further improve the fault tolerance rate of the prepared array substrate.

It should be noted that although in some embodiments, the two electrostatic discharge structures 4 are connected to both sides of the extension direction of the discharge line 3. This does not mean a limitation for the connection position of the electrostatic discharge structure 4. The connection position of the electrostatic discharge structure 4 to the discharge line 3 is also not limited in the present application. In some other embodiments, the electrostatic discharge structure 4 can be electrically connected to any position on the discharge line 3, as long as the electrostatic discharge structure 4 can discharge the static electricity accumulated on the data line 2. In the process of practical production and application, when the area of the prepared array substrate is rather small and there may be less static electricity accumulated on it. The discharge line 3 may also be electrically connected with only one electrostatic discharge structure 4. When the region of the prepared array substrate is large, a plurality of electrostatic discharge structures 4 can also be connected to the discharge line 3 to ensure that the static electricity on the substrate 1 can be fully released and the yield of the array substrate can be guaranteed. Considering the manufacturing cost and processing technology, two electrostatic discharge structures 4 are generally electrically connected to the discharge line 3.

Optionally, in some embodiments, the discharge line 3 and the data line 2 are integrally formed, that is, the discharge line 3 and the data line 2 are formed on the same layer. Specifically, in the practical production process, the discharge line 3 and the data line 2 are formed by the same patterning process, thus greatly saving the process required for setting the discharge line 3 and for connecting the discharge line 3 and the data line 2, to save the preparation time. At the same time, since the data line 2 and the discharge line 3 are integrally formed, the stability and tightness of the connection between the data line 2 and the data line 2 are more reliable, and the error rate in releasing static electricity on the data line 2 is reduced.

It should be noted that in other embodiments, the data line 2 and the discharge line 3 may not be integrally formed. By way of embodiments, the discharge line 3 may be designed and formed in advance in the non-display region 11 of the substrate 1 according to the region provided at the second end of the data line 2. And then the data line 2 may be formed on the substrate 1 so that the second end of the data line 2 is connected to the discharge line 3. It is also possible to form the data line 2 first, then design the specification of the discharge line 3 and form the discharge line 3 in the edge region 12 where the second end of the data line 2 is located, and the second end of the data line 2 and the discharge line 3 are electrically connected. In the process of practical production and application, it is necessary to determine the setting mode of the discharge line 3 and the connection between the data line 2 and the discharge line 3 according to the specific situation.

Specifically, the discharge line 3 is made of the same conductive material as the data line 2. In some embodiments, both the discharge line 3 and the data line 2 are made of copper. In other embodiments, the discharge line 3 may also be made of metals such as aluminum, molybdenum, or alloys comprising any two or three of copper, aluminum, and molybdenum. The data line 2 may be made of the same or different conductive material as the discharge line 3.

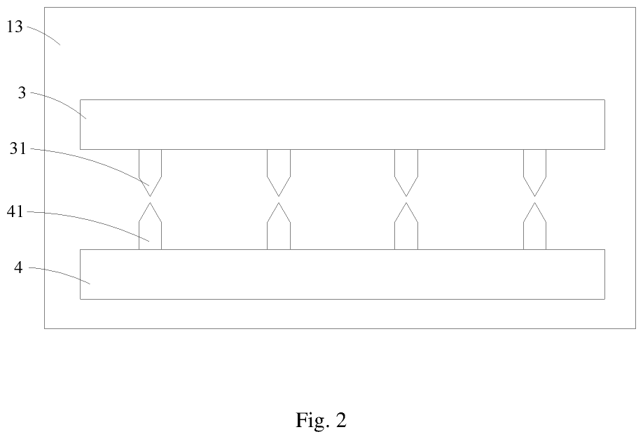

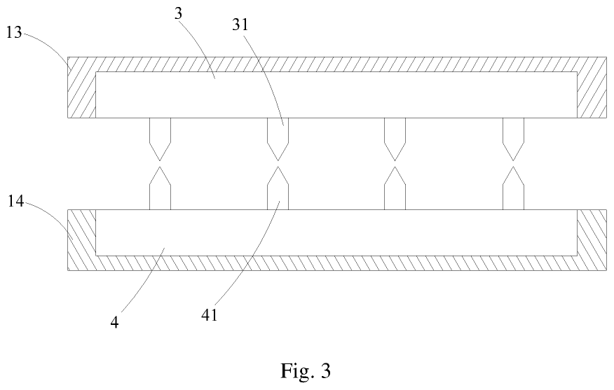

Optionally, in some embodiments, the electrostatic discharge structure 4 is a tip discharge device implemented according to the tip discharge principle. Specifically, please refer to FIG. 2. In some embodiments, the tip discharge device is provided on the data line layer 13, and a plurality of first tip structures 31 are formed on the discharge line 3. The tip discharge device has a plurality of second tip structures 41 arranged opposite to the first tip structures 31. When static electricity is generated on the data line 2, static electricity on the data line 2 will be transported to the discharge line 3 and collected on the first tip structures 31 on the discharge line 3. According to the principle of tip discharge, the charge accumulated on the first tip structures 31 will be transferred to the second tip structures 41 and be picked up by the tip discharge device. Please refer to FIG. 3, which is a schematic structural diagram of the middle discharge line 3 and the tip discharge device according to some other embodiments of the present application. In some embodiments, the discharge line 3 is defined on the data line layer 13 on the substrate 1, and the tip discharge device is defined on the gate line layer 14 on the substrate 1. In the present embodiments, the discharge line 3 and the tip discharge device are also provided with a first tip structure 31 and a second tip structure 41, respectively. Although a tip discharge device of the discharge line 3 is provided on different film layers on the substrate 1, static electricity on the discharge line 3 can still be released according to the tip discharge principle transmitted to the tip discharge device.

It should be noted that in other embodiments of the present application, the electrostatic discharge device may also be selected from an electrostatic ring. Since the electrostatic ring is already a very mature technical means, it will not be described here.

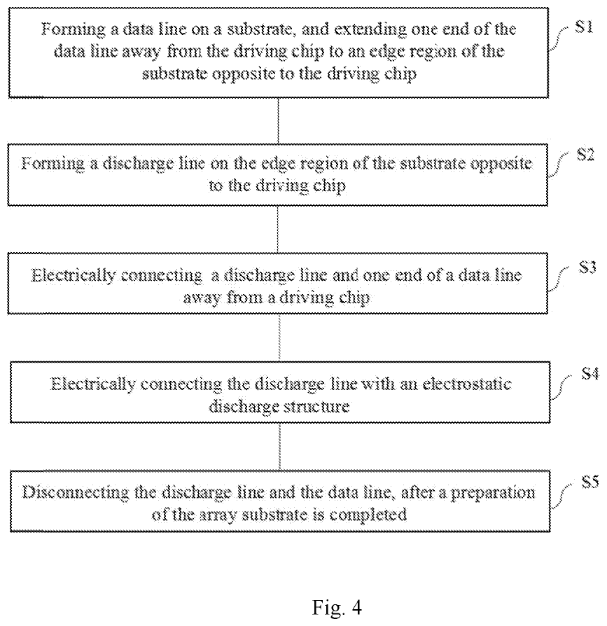

Please refer to FIG. 4, the present application also provides a manufacturing method of the array substrate, through which static electricity accumulated on the substrate can be released during the preparation of the array substrate, so as to minimize or even to prevent the occurrence of electrostatic discharge during the preparation of the array substrate. Specifically, the manufacturing method of the array substrate comprises the following steps: S1, forming a data line on the substrate, and extending one end of the data line away from the driving chip to an edge region of the substrate opposite to the driving chip; S2, forming a discharge line on the edge region of the substrate opposite to the driving chip; S3, electrically connecting a discharge line and one end of a data line away from the driving chip; S4, electrically connecting the discharge line with an electrostatic discharge structure; S5, disconnecting the discharge line and the data line, after a preparation of the array substrate is completed.

It can be understood that the method for preparing the array substrate provided by the present application enables static electricity accumulated on the substrate to be released, by means of the discharge line during the preparation of the array substrate by electrically connecting the discharge line with one end of the data line away from the driving chip and electrically connecting the discharge line with the electrostatic discharge structure. The data line and the discharge line are disconnected after the array substrate is completed, so as to facilitate subsequent use of the array substrate. Compared with the exemplary technology, the technical solution of the present application can release the static electricity accumulated on the array substrate, effectively improve the yield of products. The connection between the data line and the discharge line is cut off after the array substrate is prepared, which does not adversely affect the structure and performance of the array substrate itself, and is convenient for mass production of the array substrate.

It should be noted that the above steps are only the implementation sequence of the manufacturing method of the array substrate in some embodiments, and are for limitation of the specific steps of the method.

Specifically, in step S2, the discharge line and the data line are integrally formed, that is, the discharge line and the data line are made of the same material and formed by the same patterning process, and the discharge line and the data line are formed on the same layer.

Specifically, in step S3, all data lines are electrically connected to one discharge line, and the extension direction of the discharge line is perpendicular to the extension direction of the data lines.

Specifically, in step S4, an electrostatic discharge structure is electrically connected to both ends in the extension direction of the discharge line to release static electricity accumulated on the data line more quickly and stably. In some embodiments, the electrostatic discharge structure adopted is a tip discharge device, and the electrostatic discharge device is defined on the data layer. In other embodiments of the present application, the electrostatic discharge device may also use electrostatic ring.

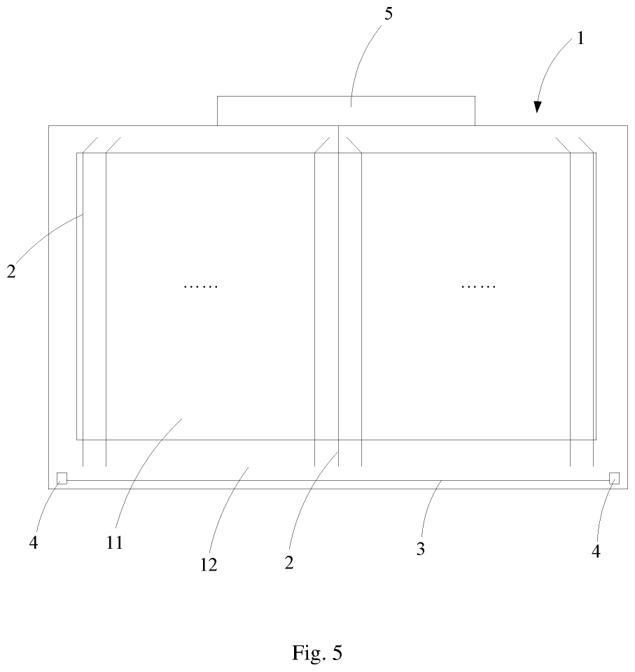

Optionally, in step S5, the data line and the discharge line is disconnected by laser cutting. Please refer to FIG. 5, which is a schematic structural diagram of the array substrate after the data line and the discharge line is disconnected in some embodiments. Specifically, in some embodiments, the laser sequentially cuts off the portion of each data line in the edge region along the extension direction of the discharge line to break the connection between the data line and the discharge line. It can be understood that the electrical connection between the data line and the discharge line can be easily and quickly disconnected by laser cutting, and in the practical production and application process, the laser cutting method only needs to add a laser cutting device to the conventional production equipment of the array substrate, and add a laser cutting process to the production process of the array substrate. So the connection between the data line and the discharge line can be disconnected, and the influence on the production line of the array substrate is small.

It should be noted that in other embodiments, since the discharge line is integrally formed with the data line, the connection between the data line and the discharge line can also be cut by laser cutting off the discharge line between adjacent data lines. In some embodiments of the present application, the electrical connection between the data line and the discharge line may also be cut by etching, which is not specifically limited in the present application.

The present application also provides a display device which comprises an array substrate prepared by using the manufacturing method of the array substrate. The specific structure of the array substrate refers to the aforementioned embodiments. Since the display device adopts the array substrate prepared by the aforementioned method, it has at least all the effects brought about by the technical solution of the aforementioned embodiment, and will not be described with detail herein.

Specifically, the display device can be a liquid crystal display device, such as a liquid crystal display, a liquid crystal television, a digital photo frame, a mobile phone, a tablet computer and other products or components with display functions, or an organic electroluminescent diode display device.

This is only some embodiments of the present application and is not intended to limit the scope of the present application. Any equivalent structural change made under the concept of the present application using the contents of the present application specification and drawings, or directly/indirectly applied in other related technical fields, shall be included in the protection scope of the present application.

What is claimed is:

1. An array substrate, comprising:
a substrate, comprising a display region and an edge region located at a periphery of the display region;
a data line, comprising a first end and a second end, the first end connecting with a driving chip, and the second end extending to the edge region along a direction away from a side of the driving chip;
a discharge line, defined in the edge region and electrically connected with the second end of the data line; and
an electrostatic discharge structure, electrically connected with the discharge line.

2. The array substrate of claim 1, wherein, an extension direction of the discharge line is perpendicular to an extension direction of the data line.

3. The array substrate of claim 1, wherein the discharge line is integrally formed with the data line.

4. The array substrate of claim 1, wherein, two sides of the extension direction of the discharge line are electrically connected with the electrostatic discharge structure.

5. The array substrate of claim 4, wherein, the electrostatic discharge structure is an electrostatic ring or a tip discharge device.

6. The array substrate of claim 1, wherein, the discharge line is electrically connected with a plurality of electrostatic discharge structures.

7. The array substrate of claim 1, wherein, there are a plurality of data lines, and each of the data lines is electrically connected with one discharge line.

8. The array substrate of claim 1, wherein, there are a plurality of discharge lines, and the plurality of discharge lines are connected to each other.

9. The array substrate of claim 1, wherein, the discharge line is made of copper.

10. The array substrate of claim 1, wherein, the electrostatic discharge structure is an electrostatic ring or a tip discharge device.

11. The array substrate of claim 10, wherein, when the electrostatic discharge structure is tip discharge device, the tip discharge device is defined on a data line layer or a gate line layer on the substrate.

12. A manufacturing method of an array substrate, comprising the operation of:
electrically connecting a discharge line and one end of a data line away from a driving chip;
electrically connecting the discharge line with an electrostatic discharge structure; and
disconnecting the discharge line and the data line, after a manufacturing of the array substrate is completed.

13. The manufacturing method of claim 12, wherein, electrically connecting a discharge line and one end of a data line away from a driving chip, comprises the following operation:
forming the data line on a substrate and extending one end of the data line away from the driving chip to an edge region of the substrate opposite to the driving chip;
forming the discharge line on the edge region of the substrate opposite to the driving chip.

14. The manufacturing method of claim 13, wherein, the discharge line is formed integrally with the data line, during forming the discharge line on the edge region of the substrate opposite to the driving chip.

15. The manufacturing method of claim 12, wherein, all the data lines are electrically connected to one discharge line, when electrically connecting the discharge line and the one end of a data line away from the driving chip.

16. The manufacturing method of claim 12, wherein, two ends of the discharge line in an extending direction are respectively electrically connected to one electrostatic discharge structure, during electrically connecting the discharge line with an electrostatic discharge structure.

17. The manufacturing method of claim 12, wherein, the electrostatic discharge structure is a tip discharge device.

18. The manufacturing method of claim 12, wherein, the electrostatic discharge structure is an electrostatic ring.

19. The manufacturing method of claim 12, wherein, the operation of disconnecting the discharge line and the data line comprises disconnecting the discharge line and the data line by laser cutting.

20. A display device, comprising an array substrate, a manufacturing method of the array substrate comprising the following operation: electrically connecting a discharge line and one end of a data line away from a driving chip;
electrically connecting the discharge line with an electrostatic discharge structure; and
disconnecting the discharge line and the data line, after a preparation of the array substrate is completed.
